(19) United States
(12) Patent Application Publication
(10) Pub. No.: US 2006/0249749 A1
(43) Pub. Date: Nov. 9, 2006

(54) Electronic device

(76) Inventor: John David Rhodes, Menston (GB)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(21) Appl. No.: 11/430,558

(22) Filed: May 9, 2006

(30) Foreign Application Priority Data
May 9, 2005 (GB) 0509376.0

(51) Int. Cl. H01L 31/00

(52) U.S. Cl. 257/192

(57) ABSTRACT

An electronic device is described which comprises: an electrically conductive p-type semiconductor layer (4,6); an electrically isolating semiconductor layer (10) formed on the p-type semiconductor layer (4,6); and at least one further transistor layer (12;14;16;18;20;22) formed on the isolating semiconductor layer (10). The electrically conductive p-type semiconductor layer (4,6) provides capacitive coupling between the electrodes (14, 18) of the device, increasing its output capacitance. This is beneficial for transistors used in high efficiency operation modes.

The present invention relates to an electronic device and in particular to power electronic devices.

It is desirable to increase the operating efficiency of power electronic devices in many applications. In order to increase the efficiency of a power electronic device various methods of operation have been proposed. This requires control of higher harmonic content, and in particular the 2^{nd} harmonic.

In order to achieve the effective control of the harmonics it has been proposed to increase the output capacitance of a power electronic device to present a low impedance to the higher harmonics, and in particular the 2^{nd} harmonic, of the signal.

The innate capacitance of devices on semi-insulating substrates, for example Gallium Arsenide (GaAs), is often very small. In order to increase the output capacitance it is therefore necessary to add significant additional capacitance external to the device itself. For a GaAs device the additional capacitance required is of the order of 10 to 20 times the intrinsic parasitic capacitance of the device itself, This is inconvenient and expensive to provide externally.

The present invention provides an electronic device including a p-type semiconductor layer. The p-type semiconductor layer can capacitively couple electrodes of the semiconductor device and act to increase the output capacitance. The resulting semiconductor device can be used more easily and cheaply in high efficiency operation modes because the need for additional external capacitance is reduced.

According to a first aspect of the present invention, there is provided an electronic device comprising:

an electrically conductive p-type Semiconductor layer;

an electrically isolating semiconductor layer formed on the p-type semiconductor layer; and

at least one further transistor layer formed on the isolating semiconductor layer.

The isolating semiconductor layer functions to isolate the active components of the device from the p-type semiconductor layer to ensure that the p-type semiconductor layer does not short circuit the electronic device and prevent its operation. The isolating layer may form part of the device itself, providing that it prevents a short circuit between other parts of the device and the p-type semiconductor layer. The at least one further transistor layer completes the construction of the electronic device and may include farther semiconductor layers or metallic layer for forming electrical connections to the device. Isolating does not mean the same as electrically insulating and the isolating layer may allow an electrical current to flow through it during operation of the device, however it will still function to isolate the further layers from the p-type semiconductor layer.

The electrically conductive p-type semiconductor layer may be a bulk p-type substrate. The p-type semiconductor layer can capacitively couple electrodes of the electronic device reduce the need for external capacitance. The p-type semiconductor layer also has the further benefit of providing a higher energy barrier for electron incursion into the substrate.

Preferably, the device farther comprises at least one aperture extending through the isolating semiconductor layer for allowing an electrical connection to the p-type semiconductor layer.

Preferably, the device further comprises at least one conductive layer formed in the at least one aperture, the at least one conductive layer being electrically connected to the p-type semiconductor layer. This ensures good capacitive coupling to the p-type layer and allows the electronic device to have an increased output capacitance.

In one embodiment the electronic device has a repeatable cell structure and for each repeat of the call structure there is one aperture and one conductive layer forming an electrical connection to the p-type semiconductor layer

The electronic device may be a field effect device, for example a MESFET or a HEMT. In this case the at least one electrically conductive layer may be the source electrode of the field effect device. The source and the drain electrodes are then capacitively coupled by the p-type layer because the p-type layer will extend beneath the device from the source to the drain. The device will also benefit from the higher energy barrier for electron incursion into the substrate provided by the p-type layer. This will reduce gate trapping effects, for example gate lag, and make the device more suitable for use in a pre-distorter because it will exhibit reduced memory effects.

Preferably, the electronic device may further comprise a semi-insulating substrate, and wherein the p-type semiconductor layer is formed on the semi-insulating substrate.

Preferably, the p-type semiconductor layer comprises a first p-type semiconductor layer and a second p-type semiconductor layer formed on the first p-type layer; and wherein the isolating semiconductor layer is formed on the second p-type semiconductor layer. By using first and second p-type layers the chemistry of each layer can be different to allow fine control over the properties of the p-type layer, for example so that it can also function as an etch stop.

Preferably the first p-type semiconductor layer is Gallium Arsenide (p⁺-Gas). Preferably the second p-type semiconductor layer is Indium Gallium Arsenide (p⁺-InGaAs). p⁺-InGaAs can be used an etch stop layer during subsequent processing of the substrate to form devices in the device layers.

Preferably the p-type layer is connected to ground. This enables the input capacitance of the device to be controlled. It can be particularly useful if the effect of grounding the p-layer increases the input capacitance by a significant amount compared to the input capacitance variation inherent in the device. This can make the input capacitance of the device less variable.

According to a second aspect of the present invention, there is provided a semiconductor substrate comprising;

an electrically conductive p-type semiconductor layer; and

an electrically isolating semiconductor layer formed on the p-type semiconductor layer.

The semiconductor substrate preferably further comprises;

at least one aperture extending through the isolating semiconductor layer for allowing an electrical connection to the p-type semiconductor layer.

Preferably, the p-type semiconductor layer comprises a fist p-type semiconductor layer and a second p-type semiconductor layer formed on the first p-type layer; and wherein the isolating semiconductor layer is formed on the second p-type semiconductor layer.

According to a third aspect of the present invention, there is provided an amplifier comprising an electronic device as described above. The amplifier can be manufactured at reduced cost for high efficiency modes of operation because there is less requirement for external capacitance to be added to increase output capacitance.

According to a fourth aspect of the present invention, there is provided a digital pre-distorted amplifier comprising an electronic device as described above. The benefits of the p-type layer to reduce electron incursion in the substrate and hence reduce trap related memory-effects make the design and construction of the pre-distorter simpler and cheaper.

Embodiments of the invention will now be described by way of example with reference to the accompanying drawings, in which:

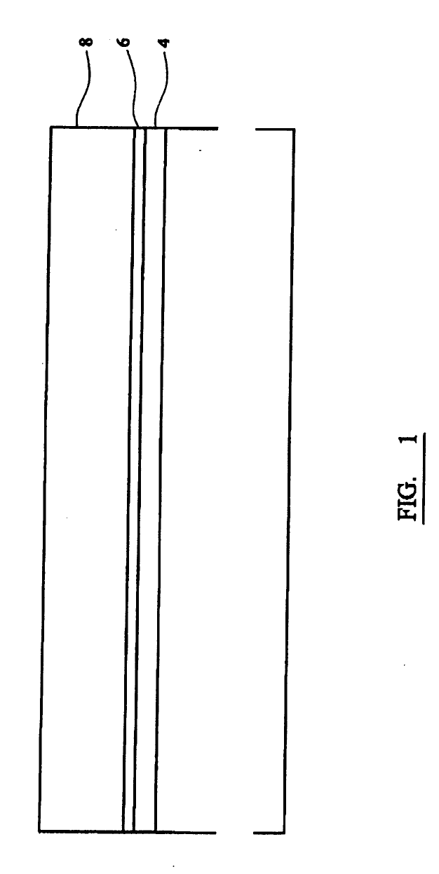

FIG. 1 depicts an embedded p-type layer in a semi-insulating substrate according to an embodiment of the present invention; and

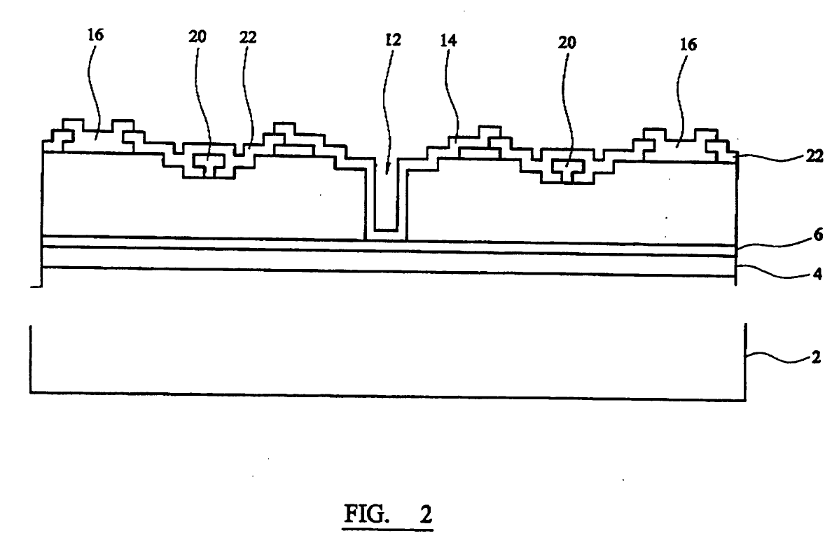

FIG. 2 depicts a field effect transistor including an embedded p-type layer according to an embodiment of the present invention

FIG. 1 depicts one embodiment of an overall substrate structure which can be used to form electronic devices according to the present invention. The substrate comprises a conventional semi-insulating base substrate 2, which is GaAs in this embodiment. On top of the base substrate 2 a first p-type semiconductor layer 4 is formed, which is p⁺-GaAs in this embodiment, A second p-type semiconductor layer 6, p⁺Indium Gallium Arsenide (p⁺-InGaAs) in this embodiment, is formed on top of the first p-type semiconductor layer 4. These layers have a thickness sufficient to ensure that they are electrically conducting and of low electrical resistance.

The electronic device itself is contained in device layers 8, which include semiconductor layers, and which are deposited using conventional techniques on top of the second p-type semiconductor layer 6.

In this way a semiconductor device can be formed which has a conducting p-type backplane formed by p-type layers 4 and 6 located beneath the semiconductor device itself. This method of manufacture allows the conducting p-type backplane to extend beneath substantially the whole of the semiconductor device formed in the device layers.

An example of a unit cell of a transistor formed using the overall substrate structure of FIG. 1 is depicted in FIG. 2. The principles governing the construction of unit cells on semiconductor substrates are well known to the person skilled in the art. The embodiment of FIG. 2 modifies a unit cell construction for use with the substrate structure depicted in FIG. 1.

The unit cell comprises an FET layer 10, which in this embodiment is formed from GaAs, formed on the second p-type semiconductor layer 6. The FET layer 10 forms pant of the unit cell and also electrically isolates any layers formed on top of it from the p-type semiconductor layer during normal operating conditions of the electronic device. The remainder of the construction of the unit cell is formed from further layers on the FET layer 10. A trench (or aperture) 12 is etched through the FET layer 10 to the second p-type semiconductor layer 6. This allows the source electrode 14 to be deposited in the trench 12 so that is in electrical contact with the second p-type semiconductor layer 6. The electrical contact formed between the source electrode and the second p-type semiconductor layer 6 has a low resistance without the need for additional process steps such as annealing.

The formation of the trench 12 during manufacture of the electronic device is simplified by the use of p⁺-InGaAs for the p-type semiconductor layer 6. The inclusion of Indium in this layer enables it to function as an etch stop during formation of the trench.

A drain electrode 16 is created at a distance from the source electrode 14. The drain electrode 16 is capacitively coupled to the p-type semiconductor layers 4 & 6. A Gate electrode 20 is positioned substantially half-way between the drain and the source. A layer of Silicon Nitride (SiNₓ) 22 is formed over the gate 20 and extends over the FET layer 10 to cover the sides of the drain electrode 16 so that the drain electrode 16 is partially covered by the SiNₓ layer 22. The SiNₓ layer 22 functions as either a passivation or an encapsulation layer.

The layers comprising the FET structure are formed using conventional lithographic techniques known to the person skilled in the art.

The construction depicted in FIG. 2 may be repeated across the surface of the substrate to produce a cellular structure. In that case it is not necessary for every source electrode to contact the p-type semiconductor layer 6, rather every other source electrode, or every third, fourth, fifth, etc. source electrode may contact the p-type layer depending on the repeat of the cellular structure. The precise interval will depend on the repeat of the unit cell used, the requirement is that for each repeat of the unit cell, there is a connection between the source and the p-type semiconductor layer 6.

In use, the p-type semiconductor layers 4 and 6 provide a conducting layer which capacitively couple the drain to the source. This significantly increases the output capacitance and makes the device especially suitable for use in high efficiency operation modes in which the impedance to the higher harmonics is required to be low.

The inclusion of the p-type layer also produces further benefits. It provides a higher energy barrier to channel electron incursion into the substrate than prior designs. The p-type layer also results in a band structure much more insensitive to the charge of any trapped electrons than a conventional semi-insulating buffer. Consequently the device has much reduced substrate trapping effects, for example gate lag. It is therefore also well suited for use in pre-distortion applications because the combination of these benefits means that it will exhibit reduced memory effects.

In a further embodiment (not shown), the p-type semiconductor layers 4 and 6 are grounded. This allows the input capacitance to the FET to be controlled and increased. This is beneficial because a large fixed capacitance on the input is useful to dominate over the input capacitance variation of the gate varactor. If the input capacitance created by the grounded p-type layer is large compared to input capacitance, the effects of variation of input capacitance can be reduced

In an alternate embodiment more or less than two p-type layers may be used provided that there is at least one and that they form a continuous p-type layer beneath the device layers. However, the use of two p-type layers is presently preferred for ease of manufacture of the device.

In yet another embodiment a device may be formed on a bulk p-type conducting semiconductor substrate and the semi-insulating substrate omitted. The bulk p-type conducting substrate will then provide the capacitive coupling and energy barrier effects. However, this embodiment is less preferred because additional process steps such as annealing are required to provide a low resistance contact between the source electrode and the p-type material.

Although the invention has been described in terms of an FET, in alternate embodiments other semiconductor devices than FETs may be formed in the device layers 8 of FIG. 1. These include other field effect devices such as a pHEMT.

In further embodiments other semi-insulating substrates than GaAs may also be used.

1. An electronic device comprising:
an electrically conductive p-type semiconductor layer;
an electrically isolating semiconductor layer formed on the p-type semiconductor layer; and
at least one further transistor layer formed on the isolating semiconductor layer.

2. An electronic device according to claim 1, further comprising at least one aperture extending through the isolating semiconductor layer for allowing an electrical connection to the p-type semiconductor layer.

3. An electronic device according to claim 2, further comprising at least one conductive layer formed in the at least one aperture, the at least one conductive layer being electrically connected to the p-type semiconductor layer.

4. An electronic device according to claim 3, wherein the electronic device has a repeatable cell structure and wherein for each repeat of the cell structure there is one aperture and one conductive layer forming an electrical connection to the p-type semiconductor layer

5. An electronic device according to claim 3, wherein the electronic device is a field effect device.

6. An electronic device according to claim 5, wherein the at least one electrically conductive layer is the source electrode of the field effect device.

7. An electronic device according to claim 1, further comprising a semi-insulating substrate, and wherein the p-type semiconductor layer is formed on the semi-insulating substrate.

8. An electronic device according to claim 1, wherein the p-type semiconductor layer comprises a first p-type semiconductor layer and a second p-type semiconductor layer formed on the first p-type layer; and wherein the isolating semiconductor layer is formed on the second p-type semiconductor layer.

9. An electronic device according to claim 8, wherein the first p-type semiconductor layer is p⁺Gallium Arsenide.

10. An electronic device according to claim 8, wherein the second p-type semiconductor layer is p⁺Indium Gallium Arsenide.

11. An electronic device according to claim 1, wherein the p-type semiconductor layer extends under substantially the whole of the isolating semiconductor layer.

12. An electronic device according to claim 1, wherein the p-type semiconductor layer is connected to ground.

13. An electronic device according to claim 1. wherein the electronic device is a field effect device, for example a MESFET or a HEMT.

14. (canceled)

15. (canceled)

16. A semiconductor substrate comprising:
an electrically conductive p-type semiconductor layer; and
an electrically isolating semiconductor layer formed on the p-type semiconductor layer.

17. A semiconductor substrate according to claim 16, further comprising:
at least one aperture extending through the isolating semiconductor layer for allowing an electrical connection to the p-type semiconductor layer.

18. A semiconductor substrate according to claim 16, wherein the p-type semiconductor layer comprises a first p-type semiconductor layer and a second p-type semiconductor layer formed on the first p-type layer; and wherein the isolating semiconductor layer is formed on the second p-type semiconductor layer.
